(19) United States
(12) Patent Application Publication
(10) Pub. No.: US 2026/0305047 A1
(43) Pub. Date: Oct. 1, 2026

(54) DISPLAY DEVICE

(71) Applicant: LG Display Co., Ltd., Seoul (KR)

(72) Inventor: HEUMEIL BAEK, Seoul (KR)

(73) Assignee: LG Display Co., Ltd., Seoul (KR)

(21) Appl. No.: 19/542,118

(22) Filed: Feb. 17, 2026

(30) Foreign Application Priority Data
Mar. 31, 2025 (KR) 10-2025-0041640

(51) Int. Cl. H10H 29/80; H10H 29/852

(52) U.S. Cl. CPC H10H 29/882; H10H 29/852

(57) ABSTRACT

A display device can include a substrate, a planarization layer disposed on the substrate, a plurality of light emitting elements disposed on the planarization layer, a plurality of hydrophobic patterns disposed on the planarization layer to cover the plurality of light emitting elements, and a decor layer disposed to surround side surfaces of the plurality of hydrophobic patterns on the planarization layer. Therefore, it is possible to improve the light extraction efficiency of the display device.

### CROSS-REFERENCE TO RELATED APPLICATIONS

This application claims priority to Korean Patent Application No. 10-2025-0041640 filed on Mar. 31, 2025, in the Korean Intellectual Property Office, the entire disclosure of which is hereby expressly incorporated by reference.

### BACKGROUND

### Field

The present disclosure relates to a display device, and more particularly, to a display device in which a deco layer can be disposed at a desired position.

### Discussion of the Related Art

Display devices used for a monitor of a computer, a TV, or a mobile phone can include an organic light emitting display (OLED) that emits light by itself, and a liquid crystal display (LCD) that requires a separate light source.

Display devices have been applied in a variety of applications, including computer monitors and TVs as well as personal portable devices, and research is being conducted on display devices that have a large display area and have a reduced volume and weight.

In addition, a display device including a light emitting diode (LED) has attracted attention as a next-generation display device. Since the LED is made of an inorganic material rather than an organic material, reliability is excellent, and a lifespan thereof is longer than that of a liquid crystal display device or an organic light emitting display device. Further, the LED has a fast lighting speed, excellent luminous efficiency, and a strong impact resistance so that a stability is excellent and an image having a high luminance can be displayed.

The description provided in the discussion of the related art section should not be assumed to be prior art merely because it is mentioned in or associated with that section. The discussion of the related art section can include information that describes one or more aspects of the subject technology, and the description in this section does not limit the disclosure.

### SUMMARY OF THE DISCLOSURE

An object to be achieved by the present disclosure is to provide a display device in which a decor layer is disposed at a desired position by utilizing an inkjet process.

Another object to be achieved by the present disclosure is to provide a display device in which a decor layer can be disposed at a desired position by utilizing a hydrophobic pattern.

Still another object to be achieved by the present disclosure is to provide a display device in which a decor layer is formed in an area non-overlapping with a light emitting element to prevent or at least reduce a decrease in light extraction efficiency.

Still another object to be achieved by the present disclosure is to provide a display device in which a hydrophobic pattern includes a plurality of scattering particles to improve light extraction efficiency.

Still another object to be achieved by the present disclosure is to provide a display device in which a diffusion layer overlapping a decor layer is disposed to improve a pattern visibility of the decor layer.

Still another object to be achieved by the present disclosure is to provide an improved display device, which can address the limitations and disadvantages associated with the related art.

Objects of the present disclosure are not limited to the above-mentioned objects, and other objects, which are not mentioned above, can be clearly understood by those skilled in the art from the following descriptions.

A display device according to an example embodiment of the present disclosure includes a substrate, a planarization layer disposed on the substrate, a plurality of light emitting elements disposed on the planarization layer, a plurality of hydrophobic patterns disposed on the planarization layer so as to cover the plurality of light emitting elements, and a decor layer disposed to surround side surfaces of the plurality of hydrophobic patterns on the planarization layer.

A display device according to another example embodiment of the present disclosure includes a substrate, a diffusion layer disposed on the substrate and including a plurality of first holes, a decor layer disposed on the diffusion layer and including a plurality of second holes overlapping the plurality of first holes, a plurality of light emitting elements disposed on the substrate so as to correspond to the plurality of first holes and the plurality of second holes, and a texture layer disposed on the decor layer and the plurality of light emitting elements.

Other detailed matters of the embodiments of the present disclosure are included in the detailed description and the drawings.

The display device according to one or more aspects of the present disclosure can control the position of the decor layer according to the difference in surface energy according to hydrophobicity and hydrophilicity.

The display device according to one or more aspects of the present disclosure can control the position of the decor layer by coating the decor layer by an inkjet process, thereby implementing process optimization.

In the display device according to one or more aspects of the present disclosure, the decor layer is disposed in an area excluding the upper portion of the light emitting element, thereby minimizing or at least reducing the luminance loss.

The display device according to one or more aspects of the present disclosure can be driven with low power by improving luminance.

In the display device according to one or more aspects of the present disclosure, a diffusion layer including scattering particles is disposed under the decor layer to effectively express the pattern of the decor layer.

The effects according to aspects of the present disclosure are not limited to the contents exemplified above, and more various effects are included in the present disclosure.

It is to be understood that both the foregoing general description and the following detailed description are example and explanatory and are intended to provide further explanation of the inventive concepts as claimed.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic block diagram of a display device according to an example embodiment of the present disclosure.

FIG. 2 is a plan view of a pixel of a display device according to an example embodiment of the present disclosure.

FIG. 3A is a cross-sectional view taken from the A-B line of FIG. 2 according to an example of the present disclosure.

FIG. 3B is an enlarged cross-sectional view of an area X of FIG. 3A according to an example of the present disclosure.

FIG. 4 is a cross-sectional view of a display device according to another example embodiment of the present disclosure.

FIG. 5 is a cross-sectional view of a display device according to still another example embodiment of the present disclosure.

FIG. 6 is a cross-sectional view of a display device according to still another example embodiment of the present disclosure.

FIG. 7 is a plan view of a display device according to still another example embodiment of the present disclosure.

FIG. 8 is a cross-sectional view taken from the C-D line of FIG. 7 according to an example of the present disclosure.

FIG. 9 is a cross-sectional view of a display device according to still another example embodiment of the present disclosure.

FIG. 10 is a cross-sectional view of a display device according to still another example embodiment of the present disclosure.

FIG. 11 is a cross-sectional view of a display device according to still another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms such as “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Any implementation described herein as an “example” is not necessarily to be construed as preferred or advantageous over other implementations.

In describing a temporal relationship, when the temporal order is described as, for example, using terms such as “after,” “subsequent,” “next,” and “before,” a case that is not continuous can be included unless a more limiting term, such as “just,” “immediate(ly),” or “direct(ly)” is used.

Further, when an element or layer is described using terms such as “connected,” “coupled,” or “adhered” to another element or layer denotes that the element or layer can not only be directly connected or adhered to the other element or layer, but also be indirectly connected or adhered to the other element or layer with one or more intervening elements or layers “disposed,” or “interposed” between the elements or layers, unless otherwise specified. It should be understood to mean that elements can be so disposed to directly contact each other, or can be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term such as “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example, consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art. Further, the term “can” fully encompasses all the meanings of the term “may” and vice versa.

Hereinafter, various embodiments of the present disclosure will be described in detail with reference to the drawings. All the components of each display device/apparatus according to all embodiments of the present disclosure are operatively coupled and configured.

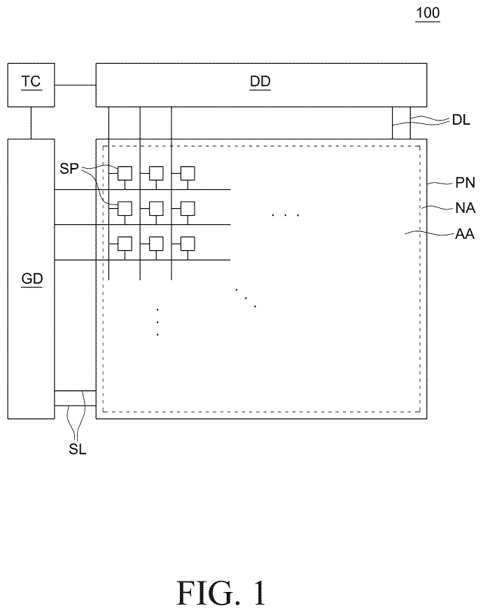

FIG. 1 is a schematic block diagram of a display device according to an example embodiment of the present disclosure.

In FIG. 1, for the convenience of description, among various components of the display device 100, a display panel PN, a gate driver GD, a data driver DD, and a timing controller TC are illustrated.

Referring to FIG. 1, the display device 100 includes the display panel PN including a plurality of sub pixels SP, the gate driver GD and the data driver DD which supply various signals to the display panel PN, and the timing controller TC which controls the gate driver GD and the data driver DD.

The driver, such as the gate driver GD, the data driver DD, and the timing controller TC, can be connected to the display panel PN in various ways. For example, the gate driver GD can be mounted in a non-display area NA (also referred to herein as a non-active area) in a gate-in-panel (GIP) manner or mounted between the plurality of sub pixels SP in a display area AA (also referred to herein as an active area) in a gate-in-active area (GIA) manner.

The display panel PN is a component for displaying an image to a user. In the display panel PN, the active area AA and the non-active area NA surrounding the active area AA can be defined.

The active area AA is an area in which images are displayed in the display device 100. In the active area AA, the plurality of sub pixels SP constituting a plurality of pixels and a circuit for driving the plurality of sub pixels SP can be disposed. The plurality of sub pixels SP is a minimum unit constituting the active area AA, and n sub pixels SP can form one pixel. In each of the plurality of sub pixels SP, a light emitting element, a thin film transistor for driving the light emitting element, and the like can be disposed. The plurality of light emitting elements can be differently defined depending on the type of the display panel PN. For example, when the display panel PN is an inorganic light emitting display panel, the light emitting element can be a micro light emitting element (LED).

In the active area AA, a plurality of signal lines for transmitting various signals to the plurality of sub pixels SP is disposed. For example, the plurality of signal lines can include a plurality of data lines DL which supplies a data voltage to each of the plurality of sub pixels SP, a plurality of scan lines SL which supplies a gate voltage to each of the plurality of sub pixels SP, and the like. The plurality of scan lines SL can extend in one direction in the active area AA and be connected to the plurality of sub pixels SP, and the plurality of data lines DL can extend in a direction different from the one direction in the active area AA and be connected to the plurality of sub pixels SP. In addition, in the active area AA, a low potential power line, a high potential power line, and the like can be further disposed, but are not limited thereto.

The non-active area NA is an area where no image is displayed, and in the non-active area NA, a link line and a pad electrode for transmitting a signal to the sub pixel SP of the active area AA, or a driving IC such as a gate driver IC and a data driver IC can be disposed.

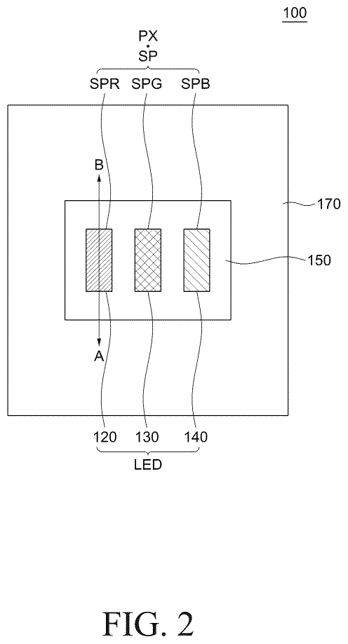

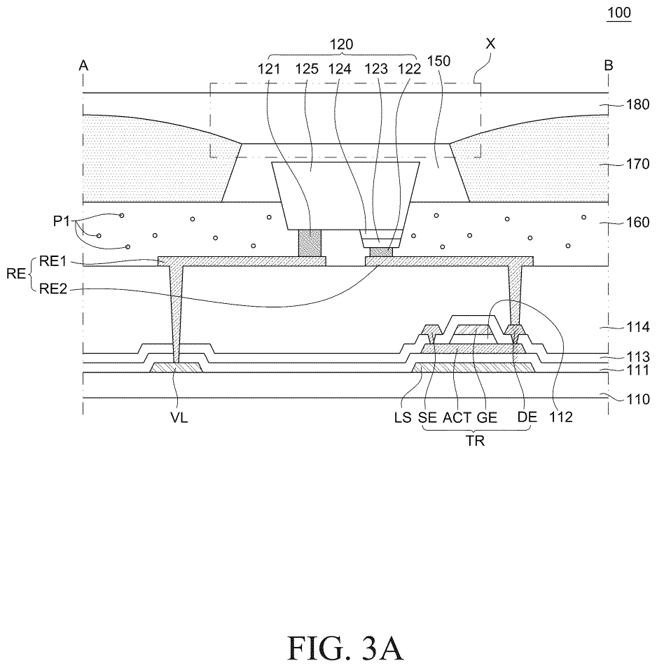

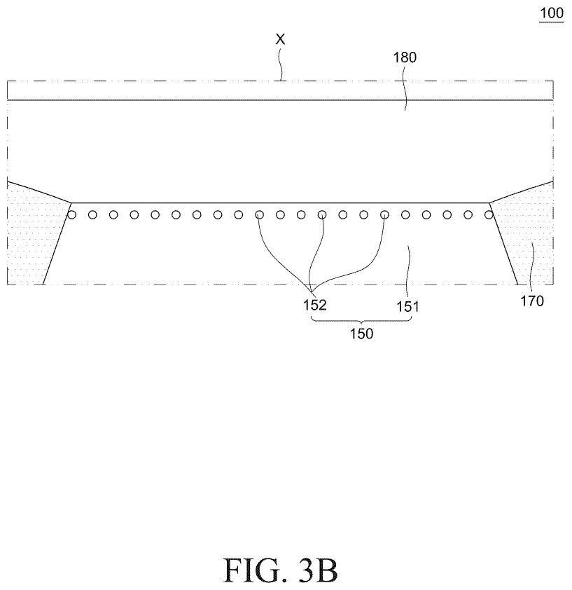

The display panel PN includes a plurality of pixels, each consisting of or including a plurality of sub pixels SP. Hereinafter, the plurality of sub pixels SP will be described in detail with reference to FIGS. 2 to 3B.

FIG. 2 is a plan view of a pixel of a display device according to an example embodiment of the present disclosure. FIG. 3A is a cross-sectional view taken from the A-B line of FIG. 2. FIG. 3B is an enlarged cross-sectional view of an area X of FIG. 3A. For example, FIG. 3A is a cross-sectional view of a first sub pixel SPR of the display device 100 according to the embodiment of the present disclosure. The second sub pixel SPG and the third sub pixel SPB can have substantially the same configuration, except for colors emitted from the first sub pixel SPR. Therefore, redundant description thereof will be omitted or may be briefly provided. For instance, each pixel of the display device 100 can have the same or similar configuration as the pixel configuration shown in FIG. 2, and each sub pixel of the display device 100 can have the same or similar configuration as the sub pixel configuration shown in FIGS. 3A and 3B.

Referring to FIG. 2, one pixel PX can include a first sub pixel SPR, a second sub pixel SPG, and a third sub pixel SPB. In this case, the first sub pixel SPR can be a red sub pixel, the second sub pixel SPG can be a green sub pixel, and the third sub pixel SPB can be a blue sub pixel, but is not limited thereto.

A plurality of light emitting elements LED can be disposed in the plurality of sub pixels SP. For example, the plurality of light emitting elements LED includes a first light emitting element 120, a second light emitting element 130, and a third light emitting element 140. The first light emitting element 120 can be disposed in the first sub pixel SPR, the second light emitting element 130 can be disposed in the second sub pixel SPG, and the third light emitting element 140 can be disposed in the third sub pixel SPB. For example, the first light emitting element 120 can be a red light emitting element, the second light emitting element 130 can be a green light emitting element, and the third light emitting element 140 can be a blue light emitting element.

Referring to FIG. 3A together, the display device 100 according to the example embodiment of the present disclosure can include a substrate 110, a buffer layer 111, a gate insulating layer 112, an interlayer insulating layer 113, a planarization layer 114, a light shielding layer LS, a diffusion layer 160, a plurality of transistors TR, a plurality of light emitting elements LED, a plurality of reflective electrodes RE, a power line VL, a plurality of hydrophobic patterns 150, a decor layer 170, and a texture layer 180.

First, the substrate 110 is a component for supporting various components included in the display device 100 and can be made of an insulating material. For example, the substrate 110 can be made of glass, resin, or the like. In addition, the substrate 110 can include polymer or plastic, or can be made of a material having flexibility.

A light shielding layer LS can be disposed on the substrate 110. The light shielding layer LS blocks light incident from below the substrate 110 progressing onto an active layer ACT of the transistor TR, which will be described below. Light incident onto the active layer ACT of the transistor TR is blocked by the light shielding layer LS to minimize or at least reduce a leakage current.

Further, the power line VL can be disposed on the substrate 110. Specifically, the power line VL can be disposed on the same layer as the light shielding layer LS and spaced apart from the light shielding layer LS. In addition, the power line VL can be formed of the same material as the light shielding layer LS, but is not limited thereto. The power line VL can be one of a low potential power line and a high potential power line. The power line VL is not limited thereto and can be disposed to be spaced apart from the source electrode SE and the drain electrode DE on the same layer as the source electrode SE and the drain electrode DE to be described later.

A buffer layer 111 can be disposed on the power line VL and the light shielding layer LS. The buffer layer 111 can reduce penetration of moisture or impurities through the substrate 110. For example, the buffer layer 111 can be configured as a single layer or multilayer made of silicon oxide (SiOx) or silicon nitride (SiNx). However, the present Disclosure is not limited thereto. However, the buffer layer 111 can be omitted depending on the type of substrate 110 or the type of transistor, but is not limited thereto. The buffer layer 111 can include a contact hole for connecting the first reflective electrode RE1 to the power line VL, which will be described below.

A plurality of transistors TR can be disposed on the buffer layer 111. The transistor TR can include an active layer ACT, a gate electrode GE, a source electrode SE, and a drain electrode DE.

The active layer ACT can be disposed on the buffer layer 111. The active layer ACT can be formed of a semiconductor material such as an oxide semiconductor, amorphous silicon, or polysilicon, but is not limited thereto.

The gate insulating layer 112 can be disposed on the active layer ACT. The gate insulating layer 112 is an insulating layer which insulates the active layer ACT from the gate electrode GE. Therefore, the gate insulating layer 112 can be disposed only between the gate electrode GE and the active layer ACT, but is not limited thereto. For example, the gate insulating layer 112 can be configured by a single layer or a double layer of silicon oxide (SiOx) or silicon nitride (SiNx), but is not limited thereto.

The gate electrode GE can be disposed on the gate insulating layer 112. The gate electrode GE can be configured by a conductive material such as copper (Cu), aluminum (Al), molybdenum (Mo), nickel (Ni), titanium (Ti), chromium (Cr), or an alloy thereof, but is not limited thereto.

The interlayer insulating layer 113 can be disposed on the gate insulating layer 112 and the gate electrode GE. The interlayer insulating layer 113 can include a contact hole for connecting the source electrode SE and the active layer ACT. The interlayer insulating layer 113 is an insulating layer which protects components below the interlayer insulating layer 113 and can be configured by a single layer or a double layer of silicon oxide (SiOx) or silicon nitride (SiNx), but is not limited thereto.

The source electrode SE and the drain electrode DE which are electrically connected to the active layer ACT can be disposed on the interlayer insulating layer 113. The source electrode SE and the drain electrode DE can be disposed to be spaced apart from each other on the same layer. The source electrode SE can be connected to the active layer ACT through a contact hole included in the interlayer insulating layer 113. The drain electrode DE can be connected to the active layer ACT through a contact hole included in the interlayer insulating layer 113. The source electrode SE and the drain electrode DE can be configured by a conductive material, such as copper (Cu), aluminum (Al), molybdenum (Mo), nickel (Ni), titanium (Ti), chrome (Cr), or an alloy thereof, but are not limited thereto.

A planarization layer 114 can be disposed on the source electrode SE and the drain electrode DE. The planarization layer 114 can planarize an upper portion of the pixel circuit including the transistor TR. The planarization layer 114 can be configured as a single layer or multilayer and made of benzocyclobutene or an acrylic-based organic material, for example. However, the present disclosure is not limited thereto.

A plurality of reflective electrodes RE is disposed on the planarization layer 114. For example, the plurality of reflective electrodes RE can include a first reflective electrode RE1 and a second reflective electrode RE2. The first reflective electrode RE1 and the second reflective electrode RE2 can be spaced apart from each other.

For example, in one sub pixel SP, the first reflective electrode RE1 can overlap the plurality of light emitting elements LED. The first reflective electrode RE1 can be connected to the power line VL through the contact holes of the planarization layer 114, the interlayer insulating layer 113, and the buffer layer 111. Therefore, the first reflective electrode RE1 can electrically connect the power line VL and the first electrode 121 of the plurality of light emitting elements LED.

The second reflective electrode RE2 can be connected to the transistor TR through a contact hole of the planarization layer 114. For example, the second reflective electrode RE2 can be connected to the drain electrode DE of the transistor TR, but is not limited thereto. Further, the second reflective electrode RE2 can be electrically connected to the second electrode 122 of the plurality of light emitting elements LED.

Each of the first reflective electrode RE1 and the second reflective electrode RE2 can include various conductive layers in consideration of light reflection efficiency and resistance. For example, each of the first reflective electrode RE1 and the second reflective electrode RE2 can use an opaque conductive layer such as silver (Ag), aluminum (Al), molybdenum (Mo), titanium (Ti), or an alloy thereof, together with a transparent conductive layer such as indium tin oxide (ITO), but is not limited thereto.

A bonding layer can be further disposed between the first reflective electrode RE1 and the first electrode 121 and between the second reflective electrode RE2 and the second electrode 122. In this case, the bonding layer can be formed to include a conductive material to electrically connect the first reflective electrode RE1 and the first electrode 121 and the second reflective electrode RE2 and the second electrode 122, respectively, but is not limited thereto. The bonding layer can be omitted according to an embodiment.

The plurality of light emitting elements LED is disposed on the first reflective electrode RE1. Referring to FIG. 3A, the first light emitting element 120 can be a flip-chip type light emitting element in which a first electrode 121 and a second electrode 122 to be described below are disposed on the same plane under the light emitting element. The first light emitting element 120 can be a lateral type light emitting element without being limited thereto.

Hereinafter, it is described that the first light emitting element 120 is a flip-chip type light emitting element. In addition, the second light emitting element 130 and the third light emitting element 140 can have substantially the same configuration as the first light emitting element 120 only having different colors from those of the first light emitting element 120.

The first light emitting element 120 includes a first electrode 121, a first semiconductor layer 125, a second electrode 122, a second semiconductor layer 123, and an emission layer 124.

The first electrode 121 of the first light emitting element 120 can be electrically connected to the power line VL through the first reflective electrode RE1. Therefore, the first electrode 121 can transmit the voltage transmitted through the power line VL to the first semiconductor layer 125. For example, the first electrode 121 can be an N-type electrode disposed to inject electrons into the emission layer 124 through the first semiconductor layer 125. The first electrode 121 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 122 can be electrically connected to the drain electrode DE of the transistor TR through the second reflective electrode RE2. Accordingly, the second electrode 122 can transmit the voltage transmitted from the drain electrode DE to the second semiconductor layer 123. For example, the second electrode 122 can be a P-type electrode for injecting holes into the emission layer 124 through the second semiconductor layer 123. The second electrode 122 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The first semiconductor layer 125 can be disposed on the first electrode 121, and the second semiconductor layer 123 can be disposed on the second electrode 122. The first semiconductor layer 125 and the second semiconductor layer 123 can be layers formed by injecting N-type or P-type impurities into a material such as indium aluminum phosphide (InAlP) or gallium arsenide (GaAs). For example, the first semiconductor layer 125 can be an N-type semiconductor layer formed by injecting an N-type impurity into gallium arsenide (GaAs), and the second semiconductor layer 123 can be a P-type semiconductor layer formed by injecting a P-type impurity into gallium arsenide (GaAs), but is not limited thereto. In this case, the N-type impurity can be silicon (Si), germanium (Ge), tin (Sn), and the like, and the P-type impurity can be magnesium (Mg), zinc (Zn), beryllium (Be), and the like, but are not limited thereto.

The emission layer 124 can be disposed between the first semiconductor layer 125 and the second semiconductor layer 123. The emission layer 124 can receive holes and electrons from the first semiconductor layer 125 and the second semiconductor layer 123 to emit light. The emission layer 124 can be formed of a single layer or a quantum well (MQW) structure.

Next, an encapsulation film which surrounds the first semiconductor layer 125, the second semiconductor layer 123, and the emission layer 124 can be further disposed. The encapsulation film is formed of an insulating material to protect the first semiconductor layer 125, the second semiconductor layer 123, and the emission layer 124.

The diffusion layer 160 can be disposed on the plurality of reflective electrodes RE.

The diffusion layer 160 is disposed between the planarization layer 114 and the plurality of hydrophobic patterns 150 and the decor layer 170. The diffusion layer 160 can cover upper and side surfaces of the first reflective electrode RE1 and the second reflective electrode RE2.

The diffusion layer 160 can be formed by a nozzle printing method or a photo printing process. For example, the diffusion layer 160 can be locally formed only in a partial area surrounding the plurality of light emitting elements LED on the substrate 110 on which the plurality of light emitting elements LED is disposed, but is not limited thereto.

The diffusion layer 160 can include a plurality of first holes which expose a part of the top surfaces of the plurality of reflective electrodes RE on the planarization layer 114. A part of a lower side of the plurality of light emitting elements LED can be disposed in the plurality of first holes, and in the plurality of first holes, the plurality of reflective electrodes RE and the plurality of light emitting elements LED can be electrically connected.

The diffusion layer 160 can surround a part of lower sides of the plurality of light emitting elements LED outside the plurality of first holes. For example, referring to FIG. 3A, the diffusion layer 160 can surround at least a part of the first electrode 121, the second electrode 122, the second semiconductor layer 123, the emission layer 124, and the first semiconductor layer 125 that are part of the lower side of the first light emitting element 120. In this case, the diffusion layer 160 can surround the side surface of the first light emitting element 120 and can be disposed to expose a part of the upper side and the top surface of the first light emitting element 120.

The diffusion layer 160 can be made of, for example, an acrylic organic material. In this case, the diffusion layer 160 can include a plurality of scattering particles P1 dispersed in an acrylic organic material. For example, the scattering particles P1 included in the diffusion layer 160 can include one or more of TiO2, ZrO2, Al2O3, In2O3, ZnO, SnO2, Sb2O3, and ITO. Therefore, the diffusion layer 160 can improve the pattern visibility of the decor layer 170 disposed thereon, but is not limited thereto.

A plurality of hydrophobic patterns 150 are disposed on the diffusion layer 160. Referring to FIG. 2, the plurality of hydrophobic patterns 150 is disposed so as to correspond to each of the plurality of pixels PX. In one pixel PX, the hydrophobic pattern 150 is disposed to cover a part of the plurality of light emitting elements LED and a part of the diffusion layer 160. Specifically, referring to FIG. 2 together, one hydrophobic pattern 150 is disposed to cover the first light emitting element 120, the second light emitting element 130, and the third light emitting element 140 disposed in one pixel PX. In addition, one hydrophobic pattern 150 is disposed in one pixel PX to cover a portion of the top surface of the diffusion layer 160 surrounding the first light emitting element 120, the second light emitting element 130, and the third light emitting element 140.

The hydrophobic pattern 150 can be formed by a nozzle printing method or a photo process. For example, the hydrophobic pattern 150 can be locally formed only in a partial area corresponding to the plurality of light emitting elements LED on the substrate 110 on which the plurality of light emitting elements LED is disposed, but is not limited thereto.

Referring to FIG. 3A, the cross-sectional width of the hydrophobic pattern 150 decreases upward. Accordingly, the width of the top surface of the hydrophobic pattern 150 can be smaller than the width of the lower surface. Further, the side surface of the hydrophobic pattern 150 can have a shape inclined in a direction adjacent to the light emitting element LED toward the top. For example, the cross-sectional shape of the hydrophobic pattern 150 can be a trapezoidal shape, but is not limited thereto.

The hydrophobic pattern 150 is disposed to cover a part of the light emitting element LED exposed from the diffusion layer 160. For example, referring to FIG. 3A, the hydrophobic pattern 150 can be disposed to surround an upper side surface of the first semiconductor layer 125 of the first light emitting element 120. In addition, the hydrophobic pattern 150 can cover a top surface of the first semiconductor layer 125 of the first light emitting element 120.

Meanwhile, each of the plurality of hydrophobic patterns 150 can be disposed so as to correspond to a plurality of second holes of the decor layer 170 to be described later. Accordingly, the top surfaces of the plurality of hydrophobic patterns 150 can be exposed from the decor layer 170 to be described later.

The hydrophobic pattern 150 can be made of a transparent material having hydrophobic properties. Referring to FIG. 3B, the hydrophobic pattern 150 can include an organic material 151 and a plurality of hydrophobic particles 152 dispersed in the organic material 151. For example, the organic material 151 of the hydrophobic pattern 150 can be formed of an acrylic organic material, and the plurality of hydrophobic particles 152 can be formed of fluorine (F)-based particles, but is not limited thereto.

Meanwhile, referring to FIG. 3B, a plurality of hydrophobic particles 152 can be disposed adjacent to the top surface of the organic material 151. For example, the plurality of hydrophobic particles 152 can be located within about 1 μm of the top surface of the hydrophobic pattern 150, but is not limited thereto.

The hydrophobic pattern 150 can be formed by heat-treating the organic material 151 and a plurality of hydrophobic particles 152 dispersed in the organic material 151. In this case, during the heat treatment process, the plurality of hydrophobic particles 152 can be guided to the upper side of the hydrophobic pattern 150. Accordingly, it can have hydrophobic properties on the top surface of the surface of the hydrophobic pattern 150, but is not limited thereto.

The decor layer 170 is disposed on the diffusion layer 160.

The decor layer 170 is a layer representing various patterns, and can form various patterns on the display surface of the display device 100. For example, the decor layer 170 can represent a pattern such as wood or metal on the display surface of the display device 100, and the pattern of the decor layer 170 can be recognized by the user. Meanwhile, the decor layer 170 can include various materials such as an inorganic pigment, an organic pigment, a dye, or ink for expressing a pattern.

The decor layer 170 can be formed by an inkjet printing process such as a nozzle printing method. For example, the decor layer 170 can be formed by curing ink formed by a printing method, but is not limited thereto.

The decor layer 170 can include a plurality of second holes overlapping the plurality of first holes of the diffusion layer 160. For example, the plurality of second holes of the decor layer 170 can be disposed to expose the top surface of the hydrophobic pattern 150 disposed in the plurality of first holes.

The decor layer 170 is disposed outside the plurality of second holes to be in contact with a portion of the plurality of hydrophobic patterns 150. For example, the decor layer 170 can be in contact with a side surface of the hydrophobic pattern 150. In this case, the decor layer 170 can surround the side surface of the hydrophobic pattern 150 and can be disposed so as not to overlap the top surface of the hydrophobic pattern 150. In addition, the decor layer 170 can be disposed so as not to overlap the light emitting element LED on a cross section.

The decor layer 170 can have a top surface that is convex upward. For example, the decor layer 170 can form a large contact angle with the hydrophobic pattern 150 due to a difference in surface energy from the hydrophobic pattern 150. Therefore, as illustrated in FIG. 3A, the thickness of the decor layer 170 can become decrease as it is adjacent to the plurality of hydrophobic patterns 150 and become thicker as it is further away from the hydrophobic pattern 150.

A texture layer 180 can be disposed on the decor layer 170 and the plurality of hydrophobic patterns 150.

The texture layer 180 can implement a texture of the display device 100. For example, the texture layer 180 can include a plurality of protrusions and recesses on the surface. Accordingly, the texture layer 180 can implement a texture on the exterior surface of the display device 100.

Meanwhile, the texture layer 180 can scatter light extracted from the light emitting element LED together with the diffusion layer 160.

The texture layer 180 can be disposed to correspond to the entire substrate 110 to cover upper portions of the decor layer 170 and the plurality of hydrophobic patterns 150. Further, the texture layer 180 can planarize upper portions of the decor layer 170 and the plurality of hydrophobic patterns 150.

Meanwhile, the display device 100 can further include a pressure sensitive adhesive (PSA) disposed below the texture layer 180 and configured to attach the decor layer 170 and the plurality of hydrophobic patterns 150, but is not limited thereto.

The decor layer contains various dyes or pigments to express patterns. Accordingly, the decor layer can have a low transmittance. For example, the decor layer can have a light transmittance of 25% to 30%. Accordingly, when the decor layer is disposed in the path of light emitted from the display device, the decor layer can reduce the luminous efficiency of the display device. Accordingly, power consumption efficiency of the display device can be lowered, and difficulty in implementing a high luminance display can occur.

Accordingly, in the display device 100 according to the example embodiment of the present disclosure, the decor layer 170 is disposed so as not to overlap the light emitting element LED to prevent or at least reduce a decrease in light emission efficiency of the display device 100 due to the decor layer 170. For example, in the display device 100 according to the example embodiment of the present disclosure, the hydrophobic pattern 150 is disposed above the light emitting element LED and the decor layer 170 is formed by a printing method so that the decor layer 170 can be disposed so as not to interfere with the path of light emitted from the light emitting element LED. Specifically, the hydrophobic pattern 150 can be formed to surround the top surface and the upper side surface of the light emitting element LED. In this case, when the decor layer 170 is printed on the substrate 110 on which the hydrophobic pattern 150 is disposed, the decor layer 170 may not be disposed on the hydrophobic pattern 150 due to a surface energy difference, but can be disposed only on the side surface of the hydrophobic pattern 150. Accordingly, the decor layer 170 may not be disposed in the front direction of the light emitting element LED. For example, although the decor layer 170 having a low light transmittance is disposed so as to surround the light emitting element LED, it may not interfere with the light emitted from the light emitting element LED traveling in the front direction. Accordingly, in the display device 100 according to the example embodiment of the present disclosure, the decor layer 170 can be disposed so as not to overlap the light emitting element LED, and a decrease in luminous efficiency of the display device 100 can be prevented or at least reduced, and the display device 100 can be driven with low power. In addition, since the decor layer 170 is formed by a printing method, process optimization can be implemented.

Further, in the display device 100 according to the example embodiment of the present disclosure, a micro light emitting diode (micro-LED) having a relatively small light source area is used as the light emitting element LED to secure the area of the decor layer 170. Accordingly, while minimizing or at least reducing the luminance loss of the display device 100, the sense of heterogeneity caused by the boundary surface of the decor layer 170 may not be recognized by the user.

Further, in the display device 100 according to the example embodiment of the present disclosure, the diffusion layer 160 surrounding the plurality of light emitting elements LED is disposed below the decor layer 170 to improve the visibility of the pattern of the decor layer 170. In order to further improve the visibility of the decor layer 170, the first reflective electrode RE1 and the second reflective electrode RE2 of the reflective electrode RE disposed below the diffusion layer 160 can be disposed to be spaced apart from each other and extend to the active area AA and the non-active area NA below the decor layer 170. For example, the diffusion layer 160 can include a plurality of scattering particles P1. Accordingly, the diffusion layer 160 can scatter light toward an upper side thereof, allow the pattern of the decor layer 170 disposed above the diffusion layer 160 to be effectively recognized by the user.

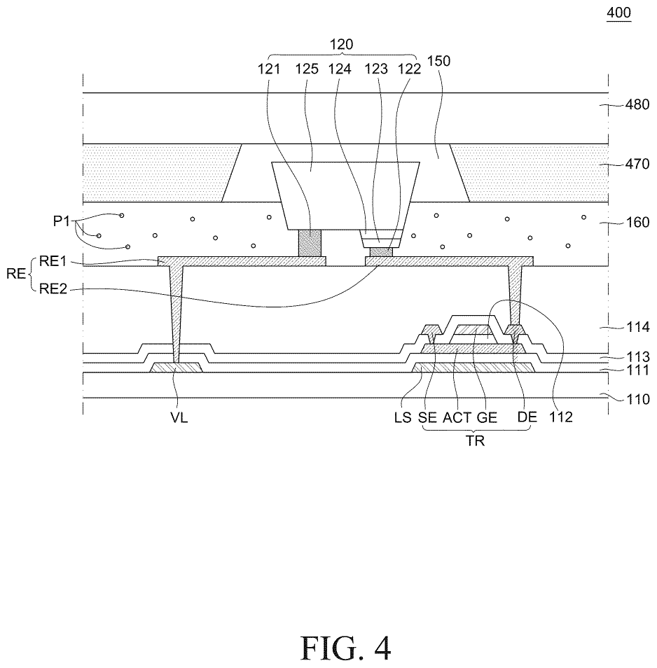

FIG. 4 is a cross-sectional view of a display device according to another example embodiment of the present disclosure. A display device 400 of FIG. 4 is different from the display device 100 of FIGS. 1 to 3B only in a decor layer 470 and a texture layer 480, and other configurations are substantially the same, so that a redundant description will be omitted or may be briefly provided.

Referring to FIG. 4, the display device 400 includes a decor layer 470 surrounding a plurality of hydrophobic patterns 150 on the diffusion layer 160.

The decor layer 470 can have a planar top surface. For example, the decor layer 470 can be disposed on the substrate 110 with the same thickness. The thickness of the decor layer 470 can be the same as the thickness of the plurality of hydrophobic patterns 150, and the top surface of the decor layer 470 and the top surface of the plurality of hydrophobic patterns 150 can be disposed on the same plane, but are not limited thereto.

Meanwhile, the thickness of the decor layer 470 can vary depending on the amount of drying. For example, when the solvent of the decor layer 470 is uniformly dried on the front surface of the substrate 110, the decor layer 470 can have a uniform thickness on the substrate 110.

The texture layer 480 is disposed on the decor layer 470 and the plurality of hydrophobic patterns 150.

The bottom surface of the texture layer 480 can cover the decor layer 470 and the top surfaces of the plurality of hydrophobic patterns 150. Therefore, the bottom surface of the texture layer 480 can be formed as a flat surface along the top surfaces of the decor layer 470 and the plurality of hydrophobic patterns 150, but is not limited thereto.

In the display device 400 according to another example embodiment of the present disclosure, the hydrophobic pattern 150 is disposed on the light emitting element LED and the decor layer 470 is disposed so as not to overlap the light emitting element LED to suppress a decrease in luminous efficiency of the display device 400 and to be driven with low power.

Further, in the display device 400 according to another example embodiment of the present disclosure, a micro light emitting diode (micro-LED) having a relatively small area is used as the light emitting element LED to minimize or at least reduce the luminance loss of the display device 400 and prevent or at least reduce the boundary surface of the decor layer 470 from being recognized.

Further, in the display device 400 according to another example embodiment of the present disclosure, the diffusion layer 160 including the plurality of scattering particles P1 is disposed below the decor layer 470 to improve the pattern visibility of the decor layer 470.

Further, in the display device 400 according to another example embodiment of the present disclosure, the solvent drying amount of the decor layer 470 can be adjusted to control the shape of the top surface of the decor layer 470. For example, the decor layer 470 can have the same thickness on the substrate 110 and can include a flat top surface.

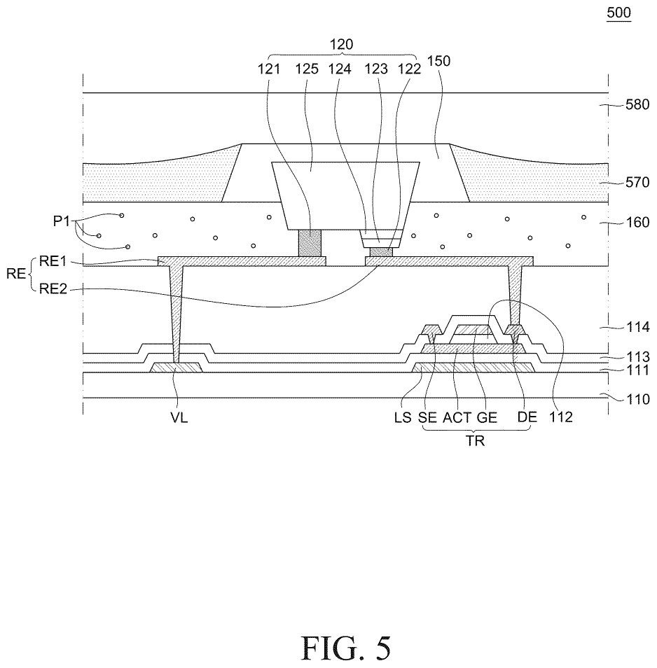

FIG. 5 is a cross-sectional view of a display device according to still another example embodiment of the present disclosure. A display device 500 of FIG. 5 is different from the display device 100 of FIGS. 1 to 3B only in a decor layer 570 and a texture layer 580, and other configurations are substantially the same, so that a redundant description will be omitted or may be briefly provided.

Referring to FIG. 5, the display device 500 includes a decor layer 570 which surrounds a plurality of hydrophobic patterns 150 on the diffusion layer 160.

The decor layer 570 can have a top surface that is concave downward.

For example, as the solvent amount of the decor layer 570 increases, the thickness of the decor layer 570 can decrease. In this case, when the plurality of hydrophobic particles 152 of the hydrophobic pattern 150 is disposed adjacent to the top surface of the organic material 151, the difference in surface energy between the side surface of the hydrophobic pattern and the side surface of the decor layer 570 may not be significant. Accordingly, the decor layer 570 can form a small contact angle with the hydrophobic pattern 150, and as illustrated in FIG. 5, the thickness of the decor layer 570 can become increase as it is adjacent to the plurality of hydrophobic patterns 150, and can decrease as it becomes farther from the hydrophobic pattern 150.

The texture layer 580 is disposed on the decor layer 570 and the plurality of hydrophobic patterns 150. A bottom surface of the texture layer 580 can cover top surfaces of the decor layer 570 and the plurality of hydrophobic patterns 150. Therefore, the bottom surface of the texture layer 580 can include a concave surface downward along the top surface of the decor layer 570, but is not limited thereto.

In the display device 500 according to still another example embodiment of the present disclosure, the hydrophobic pattern 150 is disposed on the light emitting element LED and the decor layer 570 is disposed so as not to overlap the light emitting element LED to prevent or at least reduce a decrease in light emitting efficiency of the display device 500 and can be driven with low power.

Further, in the display device 500 according to still another example embodiment of the present disclosure, a micro light emitting diode (micro-LED) having a relatively small area is used as the light emitting element LED to minimize or at least reduce the luminance loss of the display device 500 and prevent or at least reduce the boundary surface of the decor layer 570 from being recognized.

Furthermore in the display device 500 according to still another example embodiment of the present disclosure, the diffusion layer 160 including the plurality of scattering particles P1 is disposed below the decor layer 570 to improve the pattern visibility of the decor layer 570.

In addition, in the display device 500 according to still another example embodiment of the present disclosure, the solvent drying amount of the decor layer 570 is adjusted to control the shape of the top surface of the decor layer 570. For example, the decor layer 570 can have a top surface that is concave downward. The thickness of the decorative layer 570 increases as it adjacent to the plurality of hydrophobic patterns 150, and can decrease as it becomes farther.

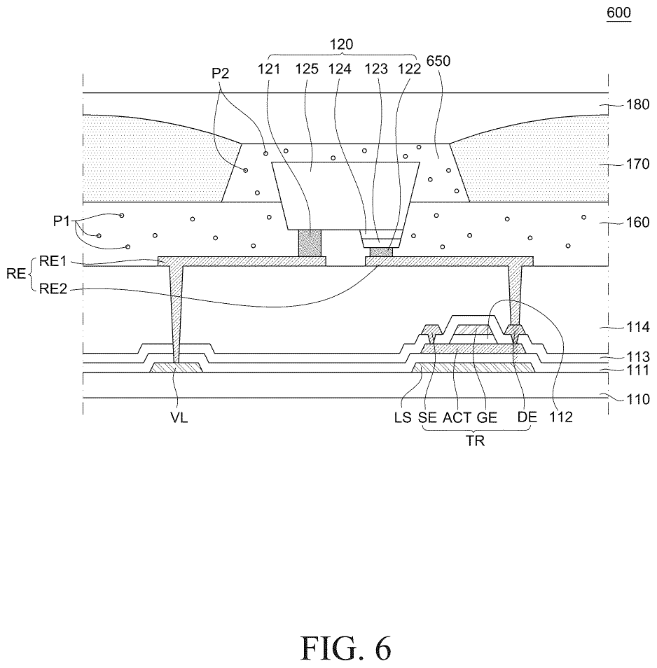

FIG. 6 is a cross-sectional view of a display device according to still another example embodiment of the present disclosure. A display device 600 in FIG. 6 is substantially identical in configuration to the display device 100 in FIGS. 1 to 3B, except for a plurality of hydrophobic patterns 650. Therefore, repeated descriptions of the identical components will be omitted or may be briefly provided.

Referring to FIG. 6, a plurality of hydrophobic patterns 650 covering a plurality of light emitting elements LED is disposed on the diffusion layer 160.

The plurality of hydrophobic patterns 650 can be made of, for example, an acrylic organic material. In this case, each of the plurality of hydrophobic patterns 650 can include a plurality of scattering particles P2 dispersed in an acrylic organic material. For example, the scattering particles P2 included in the plurality of hydrophobic patterns 650 can include one or more of TiO2, ZrO2, Al2O3, In2O3, ZnO, SnO2, Sb2O3, and ITO.

In the display device 600 according to still another example embodiment of the present disclosure, the hydrophobic pattern 650 is disposed above the light emitting element LED and the decor layer 170 is disposed so as not to overlap the light emitting element LED to suppress a decrease in luminous efficiency of the display device 600 and can be driven with low power.

Further, in the display device 600 according to still another example embodiment of the present disclosure, a micro light emitting diode (micro-LED) having a relatively small area is used as the light emitting element LED to minimize or at least reduce the luminance loss of the display device 600 and suppress the boundary surface of the decor layer 170 from being recognized.

Furthermore, in the display device 600 according to still another example embodiment of the present disclosure, the diffusion layer 160 including a plurality of scattering particles P1 is disposed below the decor layer 170 to improve the pattern visibility of the decor layer 170.

In addition, in the display device 600 according to still another example embodiment of the present disclosure, the plurality of scattering particles P2 is disposed in the plurality of hydrophobic patterns 650 disposed above the plurality of light emitting elements LED to improve the luminous efficiency of the display device 600.

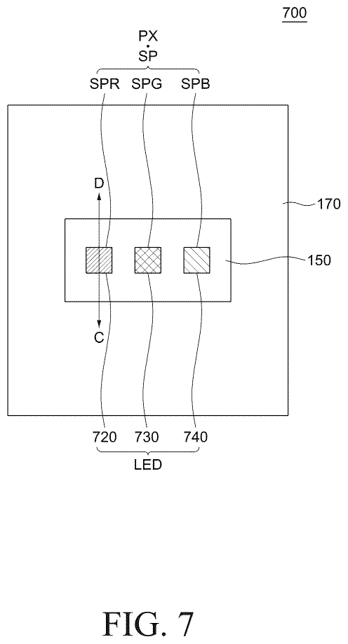

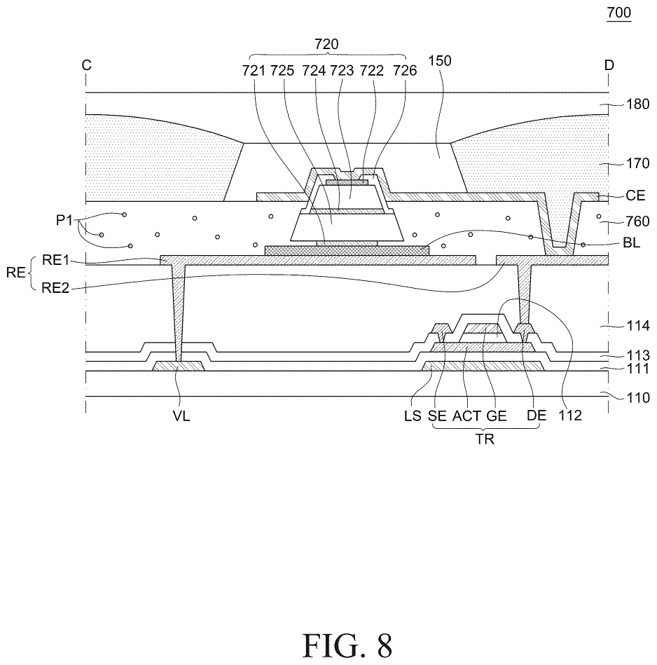

FIG. 7 is a plan view of a display device according to still another example embodiment of the present disclosure. FIG. 8 is a cross-sectional view taken from the C-D line of FIG. 7. A display device 700 of FIGS. 7 and 8 is different from the display device 100 of FIGS. 1 to 3B only in a plurality of light emitting elements LED and a diffusion layer 760, and other configurations are substantially the same, so that a redundant description will be omitted or may be briefly provided.

Referring to FIG. 8, a plurality of bonding layers BL is disposed on the first reflective electrode RE1. The bonding layer BL can include a conductive material. The bonding layer BL includes a conductive material to electrically connect the first reflective electrode RE1 and the first electrode 721 of the plurality of light emitting elements LED.

A plurality of light emitting elements LED is disposed on the plurality of bonding layers BL. Referring to FIG. 7, a first light emitting element 720, a second light emitting element 730, and a third light emitting element 740 which emit different colors can be disposed in one pixel PX. The first light emitting element 720 can emit light of the same color as the first light emitting element 120 of FIGS. 1 to 3B, the second light emitting element 730 can emit light of the same color as the second light emitting element 130 of FIGS. 1 to 3B, and the third light emitting element 740 can emit light of the same color as the third light emitting element 140 of FIGS. 1 to 3B, but is not limited thereto.

The light emitting element LED of the display device 700 of FIGS. 7 and 8 can be a vertical type light emitting element having a different structure from the light emitting element LED of FIGS. 1 to 3B. For example, referring to FIG. 8, the first light emitting element 720 can include a first electrode 721, a first semiconductor layer 725 disposed on the first electrode 721, an emission layer 724 disposed on the first semiconductor layer 725, a second semiconductor layer 723 disposed on the emission layer 724, and a second electrode 722 disposed on the second semiconductor layer 723.

The first semiconductor layer 725, the emission layer 724, the second semiconductor layer 723, and the second electrode 722 of the first light emitting element 720 are substantially identical in configuration to the first light emitting element 120 of FIGS. 1 to 3B, except for a stacking order. Therefore, repeated descriptions of the identical components will be omitted or may be briefly provided.

Meanwhile, the first light emitting element 720 can further include an encapsulation film 726 surrounding the first semiconductor layer 725, the emission layer 724, the second semiconductor layer 723, and the second electrode 722. The encapsulation film 726 can be formed of an insulating material to protect the first semiconductor layer 725, the emission layer 724, and the second semiconductor layer 723. Further, a contact hole which exposes the second electrode 722 is formed in the encapsulation film 726, so that the second electrode 722 can be electrically connected to the connection electrode CE to be described below later.

The second light emitting element 730 and the third light emitting element 740 can have substantially the same configuration as the first light emitting element 720, except for colors emitted from the second light emitting element 730 and the third light emitting element 740.

A diffusion layer 760 can be disposed on the plurality of bonding layers BL and the plurality of reflective electrodes RE.

The diffusion layer 760 can be disposed to surround the lower portions of the plurality of light emitting elements LED. For example, the diffusion layer 760 can surround at least a part of the first electrode 721, the first semiconductor layer 725, the emission layer 724, and the second semiconductor layer 723 that are part of the lower side of the first light emitting element 120.

The diffusion layer 760 can include a plurality of contact holes for connecting each of the plurality of connection electrodes CE and the plurality of second reflective electrodes RE2.

The connection electrode CE can be disposed on the diffusion layer 760 and the light emitting element LED. The connection electrode CE can electrically connect the light emitting element LED and the second reflective electrode RE2. Specifically, one end of the connection electrode CE can be connected to the light emitting element LED and the other end thereof can be connected to the second reflective electrode RE2. In this case, the connection electrode CE can be connected to the second reflective electrode RE2 through the contact hole of the diffusion layer 760. Therefore, the connection electrode CE can electrically connect the drain electrode DE of the transistor TR to the second electrode 722 of the first light emitting element 720.

The connection electrode CE can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

A plurality of hydrophobic patterns 150 and a decor layer 170 surrounding the plurality of hydrophobic patterns 150 are disposed on the connection electrode CE. And a texture layer 180 covering the plurality of hydrophobic patterns 150 and the decor layer 170 is disposed on the connection electrode CE.

In the display device 700 according to still another example embodiment of the present disclosure, the hydrophobic pattern 150 is disposed above the light emitting element LED and the decor layer 170 is disposed so as not to overlap the light emitting element LED to suppress a decrease in luminous efficiency of the display device 700 and can be driven with low power.

Further, in the display device 700 according to still another example embodiment of the present disclosure, a micro light emitting diode (micro-LED) having a relatively small area is used as the light emitting element LED to minimize or at least reduce the luminance loss of the display device 700 and prevent or at least reduce the boundary surface of the decor layer 170 from being recognized.

Furthermore, in the display device 700 according to still another example embodiment of the present disclosure, the diffusion layer 760 including a plurality of scattering particles P1 is disposed below the decor layer 170 to improve the pattern visibility of the decor layer 170.

In the display device 700 according to still another example embodiment of the present disclosure, a vertical type light emitting element having a relatively small area as the light emitting element LED is used to secure the area of the decor layer 170. For example, when the decor layer is disposed so as not to overlap the light emitting element, the area of the decor layer can decrease as the area of the light emitting element increases. Accordingly, there is a problem in that the sense of difference according to the boundary surface of the decor layer in the display device can be recognized by the user. Accordingly, in the display device 700 according to still another example embodiment of the present disclosure, the area of the decor layer 170 can be secured by using a vertical type light emitting element having a relatively small area as the light emitting element LED, and the problem that the boundary surface of the decor layer 170 is recognized by the user can be prevented or at least reduced or minimized.

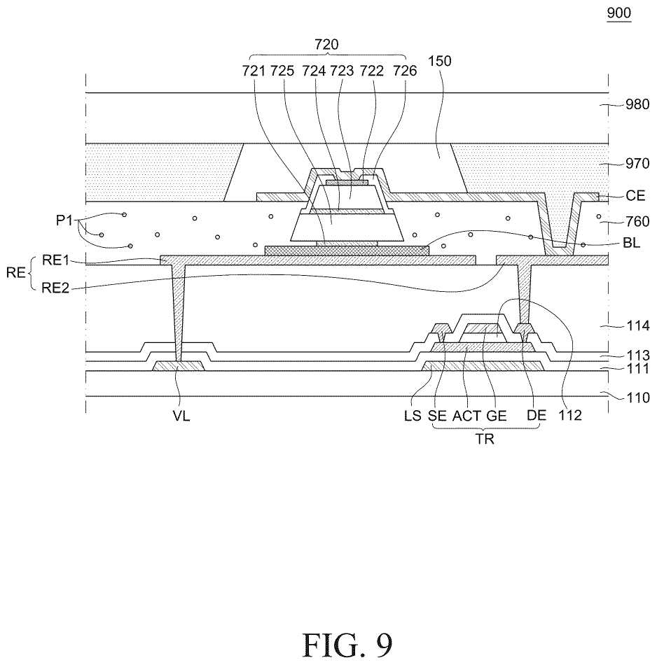

FIG. 9 is a cross-sectional view of a display device according to still another example embodiment of the present disclosure. A display device 900 of FIG. 9 is different from the display device 700 of FIGS. 7 and 8 only in a decor layer 970 and a texture layer 980, and other configurations are substantially the same, so that a redundant description will be omitted or may be briefly provided.

Referring to FIG. 9, the display device 900 includes a decor layer 970 which surrounds a plurality of hydrophobic patterns 150 on a diffusion layer 760.

The decor layer 970 can have a flat top surface. For example, the decor layer 970 can be disposed on the substrate 110 with the same thickness. In addition, a top surface of the decor layer 970 and a top surface of the plurality of hydrophobic patterns 150 can be disposed on the same plane, but are not limited thereto.

Meanwhile, the thickness of the decor layer 970 can vary depending on the amount of drying. For example, when the solvent of the decor layer 970 is uniformly dried on the front surface of the substrate 110, the decor layer 970 can have a uniform thickness on the substrate 110.

The texture layer 980 is disposed on the decor layer 970 and the plurality of hydrophobic patterns 150.

The bottom surface of the texture layer 980 can be formed as a flat surface along the top surfaces of the decor layer 970 and the plurality of hydrophobic patterns 150, but is not limited thereto.

In the display device 900 according to still another example embodiment of the present disclosure, the hydrophobic pattern 150 is disposed on the light emitting element LED and the decor layer 970 is disposed so as not to overlap the light emitting element LED to prevent or at least reduce a decrease in light emitting efficiency of the display device 900 and to be driven with low power.

Further, in the display device 900 according to another example embodiment of the present disclosure, a micro light emitting diode (micro-LED) having a relatively small area is used as the light emitting element LED to minimize or at least reduce the luminance loss of the display device 900 and prevent or at least reduce the boundary surface of the decor layer 970 from being recognized.

Furthermore, in the display device 900 according to another example embodiment of the present disclosure, the diffusion layer 760 including the plurality of scattering particles P1 is disposed below the decor layer 970 to improve the pattern visibility of the decor layer 970.

In the display device 900 according to still another example embodiment of the present disclosure, a vertical type light emitting element having a relatively small area is used as the light emitting element LED. Accordingly, the area of the decor layer 970 can be secured, and the problem that the boundary surface of the decor layer 970 is recognized by the user can be prevented or at least reduced.

Further, in the display device 900 according to another example embodiment of the present disclosure, the solvent drying amount of the decor layer 970 can be adjusted to control the shape of the top surface of the decor layer 970. For example, the decor layer 970 can have the same thickness on the substrate 110, and can include a flat top surface.

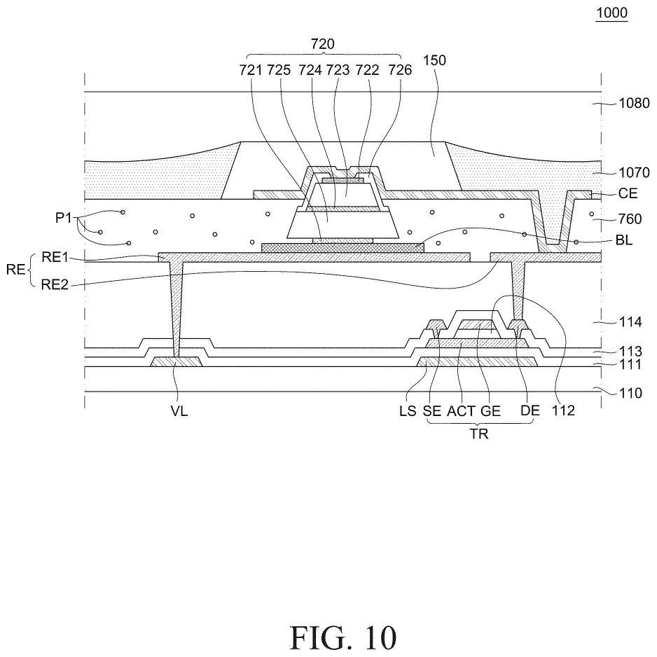

FIG. 10 is a cross-sectional view of a display device according to still another example embodiment of the present disclosure. A display device 1000 of FIG. 10 is different from the display device 700 of FIGS. 7 and 8 only in a decor layer 1070 and a texture layer 1080, and other configurations are substantially the same, so that a redundant description will be omitted or may be briefly provided.

Referring to FIG. 10, the display device 1000 includes a decor layer 1070 which surrounds a plurality of hydrophobic patterns 150 on a diffusion layer 760.

The decor layer 1070 can have a top surface that is concave downward.

For example, as the amount of solvent in the decor layer 1070 increases, the thickness of the decor layer 1070 can decrease. In this case, when the plurality of hydrophobic particles 152 of the hydrophobic pattern 150 is disposed adjacent to the top surface of the organic material 151, the difference in surface energy between the side surface of the hydrophobic pattern 150 and the side surface of the decor layer 1070 may not be significant. Accordingly, the decor layer 1070 can form a small contact angle with the hydrophobic pattern 150, and as illustrated in FIG. 10, the thickness of the decor layer 1070 can become increase as it is adjacent to the plurality of hydrophobic patterns 150 and become thinner as it is further away from the hydrophobic pattern 150.

The texture layer 1080 is disposed on the decor layer 1070 and the plurality of hydrophobic patterns 150.

The bottom surface of the texture layer 1080 can include a concave surface downward along the top surface of the decor layer 1070, but is not limited thereto.

In the display device 1000 according to still another example embodiment of the present disclosure, the hydrophobic pattern 150 is disposed on the light emitting element LED and the decor layer 1070 is disposed so as not to overlap the light emitting element LED to suppress a decrease in luminous efficiency of the display device 1000 and can be driven with low power.

Further, in the display device 1000 according to still another example embodiment of the present disclosure, a micro light emitting diode (micro-LED) having a relatively small area is used as the light emitting element LED to minimize or at least reduce the luminance loss of the display device 1000 and suppress the boundary surface of the decor layer 1070 from being recognized.

Furthermore, in the display device 1000 according to still another example embodiment of the present disclosure, the diffusion layer 760 including a plurality of scattering particles P1 is disposed below the decor layer 1070 to improve the pattern visibility of the decor layer 1070.

In the display device 1000 according to still another example embodiment of the present disclosure, a vertical type light emitting element having a relatively small area is used as the light emitting element LED. Accordingly, the area of the decor layer 1070 can be secured, and the problem that the boundary surface of the decor layer 1070 is recognized by the user can be prevented or at least reduced.

In addition, in the display device 1000 according to still another example embodiment of the present disclosure, the solvent drying amount of the decor layer 1070 can be adjusted to control the shape of the top surface of the decor layer 1070. For example, the deco layer 1070 can have a top surface that is concave downward. The closer to the plurality of hydrophobic patterns 150, the thicker and the farther away from the hydrophobic pattern 150, the thinner the thickness.

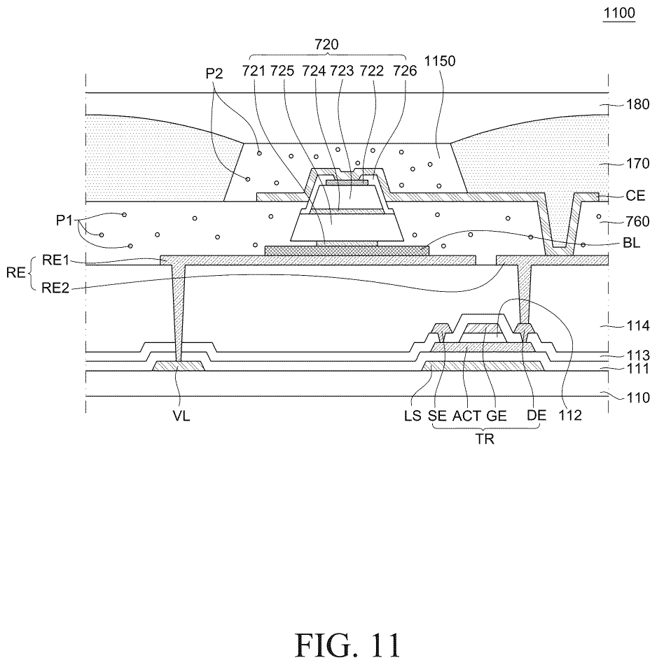

FIG. 11 is a cross-sectional view of a display device according to still another example embodiment of the present disclosure. A display device 1100 of FIG. 11 is different from the display device 700 of FIGS. 7 and 8 only in a plurality of hydrophobic patterns 1150 and other configurations are substantially the same, so that a redundant description will be omitted or may be briefly provided.

Referring to FIG. 11, a plurality of hydrophobic patterns 1150 covering a plurality of light emitting elements LED is disposed on the diffusion layer 760.

The plurality of hydrophobic patterns 1150 can be formed of, for example, an acrylic organic material. In this case, each of the plurality of hydrophobic patterns 1150 can include a plurality of scattering particles P2 dispersed in an acrylic organic material. For example, the scattering particles P2 included in the plurality of hydrophobic patterns 1150 can include one or more of TiO2, ZrO2, Al2O3, In2O3, ZnO, SnO2, Sb2O3, and ITO.

In the display device 1100 according to still another example embodiment of the present disclosure, the hydrophobic pattern 1150 is disposed on the light emitting element LED and the decor layer 170 is disposed so as not to overlap the light emitting element LED to suppress a decrease in luminous efficiency of the display device 1100 and to be driven with low power.

Further, in the display device 1100 according to still another example embodiment of the present disclosure, a micro light emitting diode (micro-LED) having a relatively small area is used as the light emitting element LED to minimize or at least reduce the luminance loss of the display device 1100 and prevent or at least reduce the boundary surface of the decor layer 170 from being recognized.

Furthermore, in the display device 1100 according to still another example embodiment of the present disclosure, the diffusion layer 760 including a plurality of scattering particles P1 is disposed below the decor layer 170 to improve the pattern visibility of the decor layer 170.

In the display device 1100 according to still another example embodiment of the present disclosure, a vertical type light emitting element having a relatively small area is used as the light emitting element LED. Accordingly, the area of the decor layer 170 can be secured, and the problem that the boundary surface of the decor layer 170 is recognized by the user can be prevented or at least reduced.

Further, in the display device 1100 according to still another example embodiment of the present disclosure, the plurality of scattering particles P2 is disposed in the plurality of hydrophobic patterns 1150 disposed above the plurality of light emitting elements LED to improve the luminous efficiency of the display device 1100.

The example embodiments of the present disclosure can also be described as follows:

A display device according to an example embodiment of the present disclosure includes a substrate, a planarization layer disposed on the substrate, a plurality of light emitting elements disposed on the planarization layer, a plurality of hydrophobic patterns disposed on the planarization layer so as to cover the plurality of light emitting elements, and a decor layer disposed so as to surround side surfaces of the plurality of hydrophobic patterns on the planarization layer.

The display device can further include a diffusion layer disposed on the planarization layer. The diffusion layer can surround a part of lower sides of the plurality of light emitting elements.

According to another feature of the present disclosure, the diffusion layer can be disposed between the planarization layer and the plurality of hydrophobic patterns and decor layers.

Each of the plurality of light emitting elements can include a first electrode, a second electrode, a first semiconductor layer disposed on the first electrode, a second semiconductor layer disposed on the second electrode, and an emission layer disposed between the first semiconductor layer and the second semiconductor layer, and the diffusion layer can surround the first electrode, the second electrode, the emission layer, and a part of a lower side of the second semiconductor layer.

Each of the plurality of light emitting elements can include a first electrode, a first semiconductor layer disposed on the first electrode, an emission layer disposed on the first semiconductor layer, a second semiconductor layer disposed on the emission layer, and a second electrode disposed on the second semiconductor layer, and the diffusion layer can surround the first electrode, the first semiconductor layer, the emission layer, and a part of a lower side of the second semiconductor layer.

The plurality of hydrophobic patterns can include an acrylic-based material and a plurality of fluorine-based particles disposed adjacent to a top surface of the acrylic-based material.

Each of the plurality of hydrophobic patterns can include a plurality of scattering particles.

According to another feature of the present disclosure, the decor layer can have a flat top surface.

According to another feature of the present disclosure, the decor layer can have a top surface that is convex upward.

According to another feature of the present disclosure, the decor layer can have a top surface that is concave downward.

According to another feature of the present disclosure, the display device can further include a decor layer and a texture layer disposed on the plurality of hydrophobic patterns.

A display device according to another example embodiment of the present disclosure includes a substrate, a diffusion layer disposed on the substrate and including a plurality of first holes, a decor layer disposed on the diffusion layer and including a plurality of second holes overlapping the plurality of first holes, a plurality of light emitting elements disposed on the substrate so as to correspond to the plurality of first holes and the plurality of second holes, and a texture layer disposed on the decor layer and the plurality of light emitting elements.

According to another feature of the present disclosure, the diffusion layer can include an acrylic material and a plurality of scattering particles dispersed in the acrylic material.

The display device can further include a plurality of hydrophobic patterns which is disposed in the plurality of second holes to cover the plurality of light emitting elements.

According to another feature of the present disclosure, the thickness of the decor layer can decrease as it is adjacent to the plurality of hydrophobic patterns.

According to another feature of the present disclosure, the thickness of the decor layer can become increase as it is adjacent to the plurality of hydrophobic patterns.

Each of the plurality of hydrophobic patterns can include a plurality of scattering particles.

Further, according to another features of the present disclosure, the display device can further include a reflective electrode disposed below the plurality of light emitting elements, and a plurality of bonding layers disposed between the reflective electrode and the plurality of light emitting elements, wherein the plurality of bonding layers includes a conductive material to electrically connect the reflective electrode and a first electrode of the plurality of light emitting elements

Although the example embodiments of the present disclosure have been described in detail with reference to the accompanying drawings, the present disclosure is not limited thereto and can be embodied in various forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate;
a planarization layer disposed on the substrate;
a plurality of light emitting elements disposed on the planarization layer;
a plurality of hydrophobic patterns disposed on the planarization layer so as to cover the plurality of light emitting elements; and
a decor layer disposed on the planarization layer so as to surround at least a portion of side surfaces of the plurality of hydrophobic patterns.

2. The display device according to claim 1, further comprising:
a diffusion layer disposed on the planarization layer,
wherein the diffusion layer surrounds a part of lower sides of the plurality of light emitting elements.

3. The display device according to claim 2, wherein the diffusion layer is disposed between the planarization layer and the plurality of hydrophobic patterns and between the planarization layer and the decor layer.

4. The display device according to claim 2, wherein each of the plurality of light emitting elements includes:
a first electrode;
a second electrode;
a first semiconductor layer disposed on the first electrode;
a second semiconductor layer disposed on the second electrode; and
an emission layer disposed between the first semiconductor layer and the second semiconductor layer.

5. The display device according to claim 4, wherein the diffusion layer surrounds at least parts of the first electrode, the second electrode, and the emission layer, and a part of a lower side of the second semiconductor layer.

6. The display device according to claim 2, wherein each of the plurality of light emitting elements includes:
a first electrode;
a first semiconductor layer disposed on the first electrode;
an emission layer disposed on the first semiconductor layer;
a second semiconductor layer disposed on the emission layer; and
a second electrode disposed on the second semiconductor layer, and
wherein the diffusion layer surrounds the first electrode, the first semiconductor layer, the emission layer, and a part of a lower side of the second semiconductor layer.

7. The display device according to claim 1, wherein the plurality of hydrophobic patterns includes:
an acrylic-based material, and
a plurality of fluorine-based particles disposed adjacent to a top surface of the acrylic-based material.

8. The display device according to claim 7, wherein each of the plurality of hydrophobic patterns includes a plurality of scattering particles.

9. The display device according to claim 1, wherein the decor layer has a flat top surface.

10. The display device according to claim 1, wherein the decor layer has a top surface that is convex upward.

11. The display device according to claim 10, wherein each of the plurality of hydrophobic patterns includes a plurality of scattering particles dispersed in an acrylic organic material.

12. The display device according to claim 1, wherein the decor layer has a top surface that is concave downward.

13. The display device according to claim 1, further comprising:
a texture layer disposed on the decor layer and the plurality of hydrophobic patterns.

14. A display device, comprising:
a substrate;
a diffusion layer disposed on the substrate and including a plurality of first holes;
a decor layer disposed on the diffusion layer and including a plurality of second holes overlapping the plurality of first holes;
a plurality of light emitting elements disposed on the substrate so as to correspond to the plurality of first holes and the plurality of second holes; and
a texture layer disposed on the decor layer and the plurality of light emitting elements.

15. The display device according to claim 14, wherein the diffusion layer includes an acrylic material and a plurality of scattering particles dispersed in the acrylic material.

16. The display device according to claim 15, further comprising:
a plurality of hydrophobic patterns disposed in the plurality of second holes to cover the plurality of light emitting elements.

17. The display device according to claim 16, wherein a thickness of the decor layer decreases as the decor layer is adjacent to the plurality of hydrophobic patterns.

18. The display device according to claim 16, wherein a thickness of the decor layer increases as the decor layer is adjacent to the plurality of hydrophobic patterns.

19. The display device according to claim 16, wherein each of the plurality of hydrophobic patterns includes a plurality of scattering particles.

20. The display device according to claim 14, further comprising:
a reflective electrode disposed below the plurality of light emitting elements; and
a plurality of bonding layers disposed between the reflective electrode and the plurality of light emitting elements,
wherein the plurality of bonding layers includes a conductive material to electrically connect the reflective electrode and a first electrode of the plurality of light emitting elements.
